(19) United States
(12) Patent Application Publication
(10) Pub. No.: US 2007/0034784 A1
(43) Pub. Date: Feb. 15, 2007

(54) Photosensitive device that easily achieves a required photosensitive response

(75) Inventor: Kuo-Chen Tsai, Hsinchu (TW)

Correspondence Address: BIRCH STEWART KOLASCH & BIRCH, PO BOX 747, FALLS CHURCH, VA, 22040-0747, US

(73) Assignee: Silicon Touch Technology Inc.

(21) Appl. No.: 11/408,943

(22) Filed: Apr. 24, 2006

(30) Foreign Application Priority Data
Aug. 15, 2005 (TW) 094127746

(51) Int. Cl. H01L 27/14

(52) U.S. Cl. 250/226; 250/239; 250/208.1; 257/431

(57) ABSTRACT

A photosensitive device has packaging elements, a sensor chip and a light-filtering layer. The packaging elements include encapsulant to cover, environmentally seal and protects the photosensitive device against damage from external contaminants and moisture. The sensor chip has a top and a photosensitive area formed on the top. The light-filtering layer filters light that emits on the photosensitive area of the sensor chip to achieve a desired photosensitive response and is mounted to the photosensitive area with a transparent adhesive layer.

### BACKGROUND OF THE INVENTION

1. Field of the Invention

The invention provides a photosensitive device, more particularly, a photosensitive device that easily achieves a required photosensitive response and the packaging cost can be reduced significantly.

2. Description of Related Art

A conventional photosensitive element is made of silicon photodiodes with one or more different optical characteristics to obtain a needed photosensitive curve. With reference to FIGS. 4 and 5, an ideal photosensitive response can be achieved by a photosensitive element using two silicon photodiodes (PD1, PD2) with different optical characteristics. The two photodiodes (PD1, PD2) have different photosensitive responses.

With further reference to FIG. 6, a circuit to implement the ideal photosensitive curve comprises four transistors (Q1, Q2, Q3, Q4) with individual collectors and emitters and two silicon photodiodes (PD1, PD2) to produce an output current (Iout). The first transistor (Q1) and second transistor (Q2) form a first current mirror (not numbered) with an amplification factor of n. The first transistor (Q1) serves as a reference terminal, and the second transistor (Q2) is a mirror terminal. The third transistor (Q3) and fourth transistor (Q4) form a second current mirror (not numbered) with an amplification factor of m. The third transistor (Q3) is the reference terminal, and the fourth transistor (Q4) is the mirror terminal. The first transistor (Q1) is connected to the third transistor (Q3) through the first silicon photodiode (PD1). The collectors of the second transistor (Q2) and fourth transistor (Q4) are also connected to an output terminal (not numbered). The second silicon photodiode (PD2) is connected to the collector of the first transistor (Q1) and the emitter of the third transistor (Q3). When light shines on the silicon photodiodes (PD1, PD2), the silicon photodiodes respectively produce a first current (Ip1) and a second current (Ip2). A first mirror current (I₁) on the collector of the second transistor (Q2) is the product of the amplification factor (n) of the first current mirror and the sum of the first current (Ip1) and the second current (Ip2) generated by the silicon photodiodes (PD1, PD2). A second mirror current (12) on the collector of the fourth transistor (Q4) is the product of the amplification factor (m*) of the second current mirror and the first current (Ip1) generated by the first silicon photodiode (PD1). Since the sum of all currents at a node in a circuit is zero, the output current (lout) at an output node (not numbered) between the collectors of the second and fourth transistors (Q2, Q4) is the arithmetic sum of the mirror currents (I1, I2), and is represented by the formula Iout=I2−I1. A graph of the output current (Iout) closely approximates the ideal photosensitive response.

However, the disadvantage is that each photosensitive response is fixed. Therefore, even when multiple silicon photodiodes are used in the circuit, the circuit still cannot precisely create the required photosensitive response.

To solve the above-mentioned problem, another conventional approach to create a required photosensitive response uses a light-filtering film. Current image sensors use such a method to sense an image. The method senses and separates the different color components of an image and recombines them into a complete image.

With reference to FIG. 7, a conventional image sensor that uses the method previously described is formed on a substrate (71) under which multiple tin balls (72) are attached to connect the substrate to a circuit board, and on which multiple enclosures (75) are formed on a surface of the substrate (71). Each enclosure (75) has an enclosure interior (not numbered). Then a photosensitive chip (73) is bonded to the surface of the substrate (71) respectively inside the enclosures (75). The photosensitive chip (73) can be electrically connected to the substrate (71) by bonding wires. The enclosure interiors may be vacuumed to remove any debris and particles. The enclosure (75) is packaged by mounting a glass cover (74) over the enclosure interior. With reference to FIG. 8, another conventional packaging structure first bonds a photosensitive element (81) to a transparent glass by using a flip-chip packaging process. The glass and the photosensitive element (81) are then packaged by a traditional semiconductor fabrication process, and multiple conductor tin balls are mounted under the substrate.

The above-mentioned methods can produce the needed photosensitive response, but the fabrication process is more complicated, the yield is lower, and the cost relatively increases.

### SUMMARY OF THE INVENTION

The main objective of the invention is to provide a photosensitive device that is easy to produce and has a response that closely approximates a needed photosensitive response. Using preferred light-filtering and the packaging technologies not only simplifies the fabrication process of the photosensitive device but also provides a response approximating the photosensitive response needed.

To achieve the main objective, a first embodiment of the photosensitive device comprises a sensor chip, a light-filtering layer and a package body that has a substrate and an encapsulant. The sensor chip is bonded on the substrate and has a top and a photosensitive area formed on the top. The light-filtering layer is transparent and bonded to said photosensitive area using a transparent adhesive layer. The encapsulant of the package body encapsulates said sensor chip and said light-filtering layer to form a complete photosensitive device and protects the sensor chip and the light-filtering layer against damage from external contaminants or moisture.

A second embodiment of the photosensitive device comprises a lead frame, a sensor chip, a light-filtering layer and a package and has a structure very similar to the first embodiment. However, the lead frame has a die pad and multiple terminals, and the sensor chip is bonded to the die pad and connects to the multiple terminals. Otherwise, the other elements are the same.

### BRIEF DESCRIPTION OF THE DRAWINGS

FIG. 1 is a side view in partial section of a first embodiment of a photosensitive device in accordance with the present invention;

FIG. 2 is a side view in partial section of a second embodiment of the photosensitive device in accordance with the present invention;

FIG. 3 is a graph of a required photosensitive response and a response of a conventional photosensitive device and a photosensitive device in accordance with the present invention;

FIG. 4 is a graph of an ideal photosensitive response;

FIG. 5 is a graph of photosensitive responses of two different conventional photodiodes;

FIG. 6 is a circuit diagram of a conventional device to implement the ideal photosensitive response in FIG. 4;

FIG. 7 is a side view in partial section of a conventional image sensor in accordance with the prior art; and

FIG. 8 is a side view in partial section of another conventional image sensor in accordance with the prior art.

### DETAILED DESCRIPTION OF THE PREFERRED EMBODIMENT

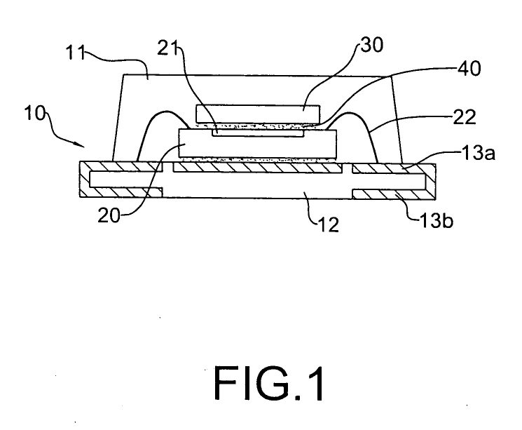

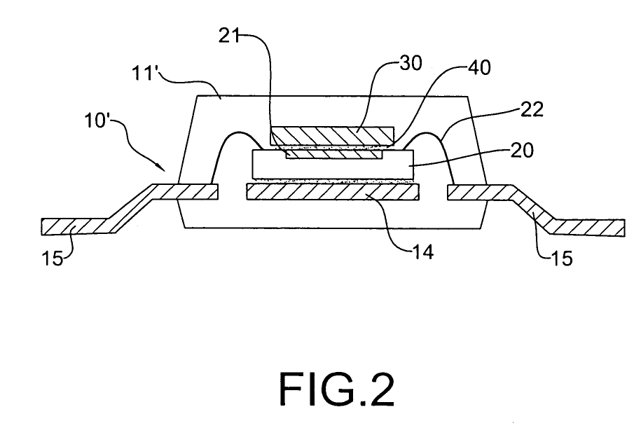

With reference to FIGS. 1 and 2, a photosensitive device in accordance with the present invention comprises packaging elements (10, 10′), a sensor chip (20), a light-filtering layer (30).

The packaging elements (10) comprise an optional substrate (12), encapsulant (11, 11′) and an optional lead frame (not numbered).

A first embodiment of the photosensitive device in accordance with the present invention uses the substrate (12) that has a top surface (not numbered), a bottom surface (not numbered), a top wire layer (13a) and a bottom wire layer (13b). The top wire layer (13a) is formed on the top surface. The bottom wire layer (13b) is formed on the bottom surface and connected electrically to the top wire layer (13b) and is to be connected to other circuit boards (not shown).

The encapsulant (11, 11′) is transparent, covers and environmentally seals the photosensitive device, is formed by using a conventional molding process and can be a resin compound such as epoxy resin. The encapsulant (11, 11′) protects the photosensitive device against damage from external moisture or contaminants.

A second embodiment of the photosensitive device in accordance with the present invention uses the lead frame that has a die pad (14) and multiple pins (15). The pins (15) protrude from the encapsulant (11′) to connect to other circuit boards (not shown).

The sensor chip (20) has a top, a photosensitive area (21) and is either a photo sensor chip or an image sensor chip. In the first embodiment of the photosensitive device, the sensor chip (20) is bonded on the top surface of the substrate (12) and is electrically connected to the top wire layer (13a). In the second embodiment of the photosensitive device, the sensor chip (20) is bonded on die pad (14) of the lead frame. The photosensitive area (21) is formed on the top of the sensor chip (20). In the first embodiment of the photosensitive device, the wires (22) connect the sensor chip (20) to the top wire layer (13a) on the substrate (12). In the second embodiment of the photosensitive device, the wires connect the sensor chip (20) to the pins (15) on the lead frame.

The light-filtering layer (30) can be glass or other materials that are transparent to filter light and is mounted on the photosensitive area (21) with a transparent adhesive layer (40), for example acrylic, plastic, compound or epoxide. By changing material of the light-filtering layer (30), different filtering effects can be achieved to filter out any light with undesired wavelength. Because the encapsulant (11,11′), the light filtering layer (30) and the adhesive layer (40) all have the light-filtering effects, the light with the undesired wavelength can be filtered out by these layers (11,11′)(30)(40) when the light sequentially passing through the encapsulant (11,11′), the light filtering layer (30) and the adhesive layer (40). The photosensitive area (21) receives only the light with the desired wavelength. For some materials of the encapsulant (11,11′) and the adhesive layer (40), the light-filtering effects of the encapsulant (11, 11′) and the adhesive layer (40) are not significant and are ignored when compared to the light-filtering effects of the light filtering layer (30). Thus, only the light-filtering effect of the light filtering layer (30) is considered.

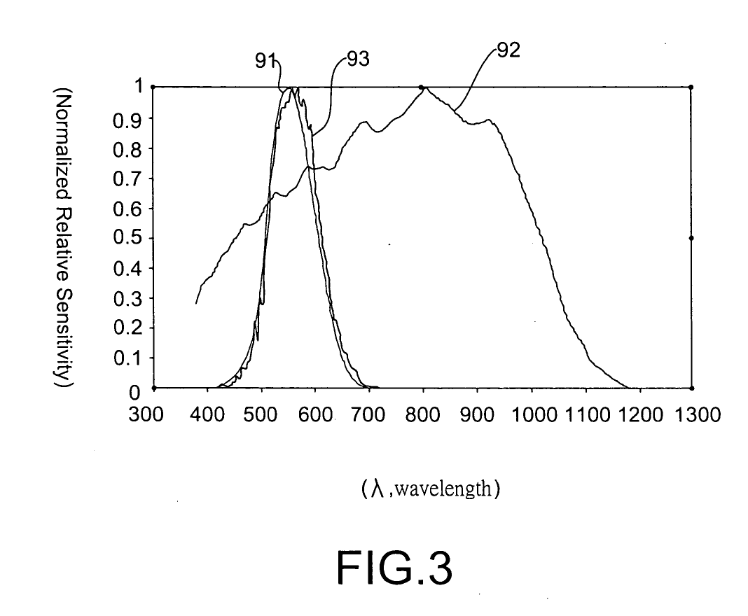

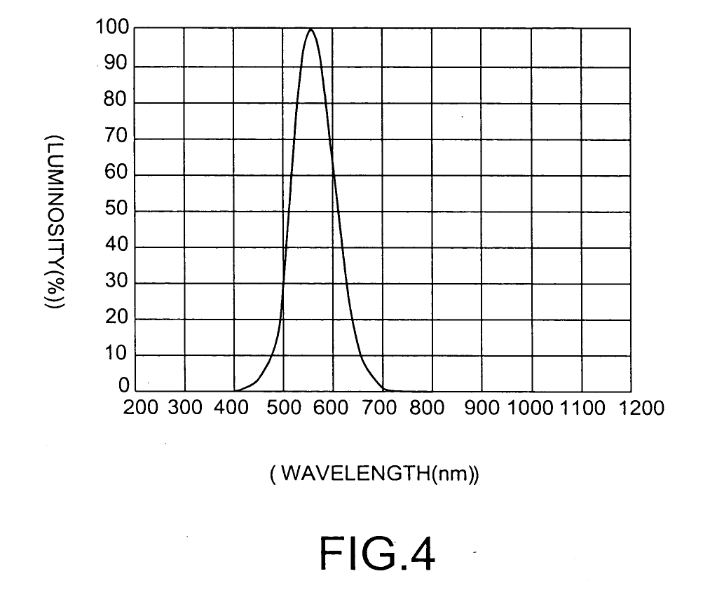

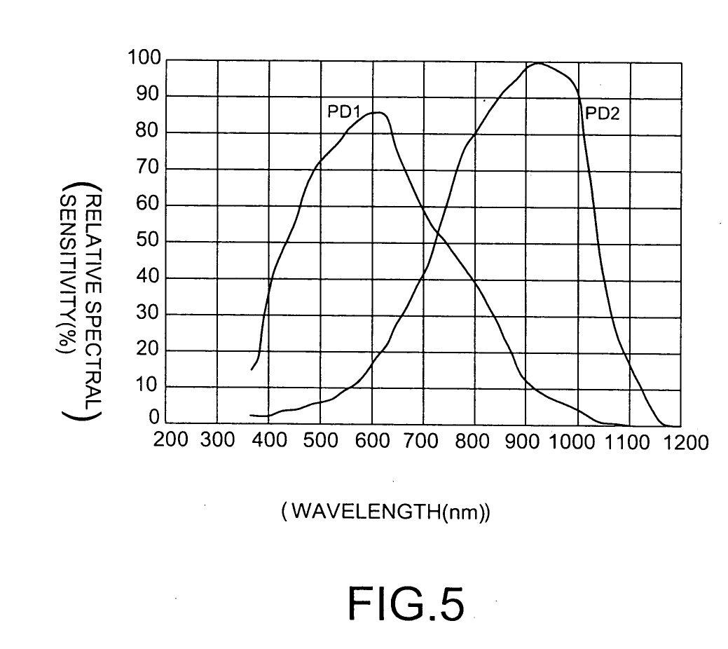

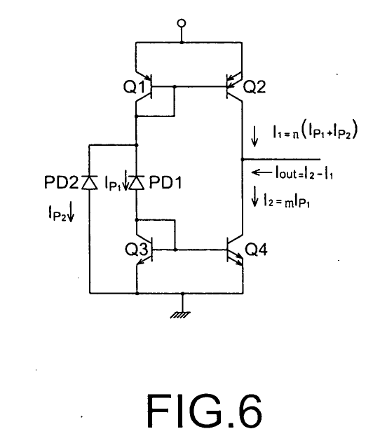

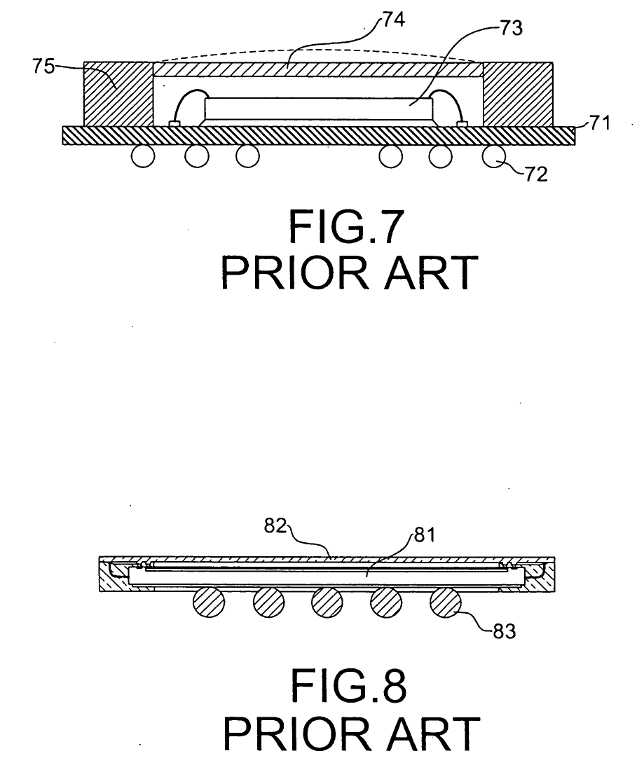

With reference to FIG. 3, a conventional silicon chip has a photosensitive response (92) that differs substantially from a desired photosensitive response (91). The photosensitive device has a photosensitive response (93) that closely approximates the desired photosensitive response (91).

As described, the photosensitive device combines an optical light-filtering element and a sensor chip to produce the desired photosensitive response. The invention not only reduces the circuit complexity, but also acquires the photosensitive response required.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A photosensitive device that easily achieves a desired photosensitive response, the photosensitive device comprising:
a sensor chip having a photosensitive area;
a light-filtering layer bonded to the photosensitive area of the sensor chip with a transparent adhesive layer; and
packaging elements on which the sensor chip is mounted and encapsulating the sensor chip and the light-filtering layer to form a complete photosensitive device.

2. The photosensitive device as claimed in claim 1, wherein said sensor chip is a photo sensor chip.

3. The photosensitive device as claimed in claim 1, wherein said sensor chip is an image sensor chip.

4. The photosensitive device as claimed in claim 1, wherein said light-filter layer is glass, transparent material, acrylic, plastic, compound or epoxide.

5. The photosensitive device as claimed in claim 1, the packaging elements comprising:
a substrate having
a top surface;
a bottom surface;
a top wire layer formed on the top surface and connecting to the sensor chip; and
a bottom wire layer formed on the bottom surface and electrically connecting to the top wire layer; and
an encapsulant being transparent and encapsulating the sensor chip and the light-filtering layer.

6. The photosensitive device as claimed in claim 1, wherein
the package body further comprises:
a lead frame having
a die pad to which the sensor chip is bonded;
multiple pins; and
wires electrically connecting the sensor chip to the pins; and
an encapsulant being transparent and encapsulating the sensor chip, the die pad and the light-filtering layer.
